(19) United States
(12) Patent Application Publication
(10) Pub. No.: US 2007/0170427 A1
(43) Pub. Date: Jul. 26, 2007

(54) Semiconductor device

(75) Inventor: Kanta Saino, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/654,501

(22) Filed: Jan. 18, 2007

(30) Foreign Application Priority Data
Jan. 20, 2006 (JP) 2006-012716

(51) Int. Cl. H01L 29/04

(52) U.S. Cl. 257/50

(57) ABSTRACT

A semiconductor device comprises a semiconductor substrate, a MOS transistor and an antifuse element. The MOS transistor is formed on the semiconductor substrate and comprises a channel region and a gate electrode. The channel region has a predetermined conductive type. The antifuse element is formed on the semiconductor substrate and comprises a predetermined region and an antifuse electrode. The predetermined region has the predetermined conductive type and is formed by the channel region forming process. The antifuse electrode is formed by the gate electrode forming process. Preferably, the antifuse element is also of the predetermined conductive type.

### BACKGROUND OF THE INVENTION:

This invention relates to a semiconductor device such as a dynamic random access memory (DRAM) device and, in particular, to an antifuse element included therein.

For example, antifuse elements are utilized for programming alterable circuit connections within an integrated circuit device or for replacing defective memory cells with redundant memory cells within a DRAM device. One type of antifuse element is disclosed in US 2004/0051162 A1, which is incorporated herein by reference in its entirety.

The disclosed antifuse element comprises a semiconductor substrate with a nitrogen (N₂)-doped surface. The N₂-doped surface can thin an insulator layer formed thereon so that the antifuse element can operate at a reduced programming voltage.

It is however required to dope an abundance of boron (B) impurities in the semiconductor substrate in order to ensure a post-breakdown resistance lowered even in the N₂-doped surface. Because the boron doping is not carried out by using manufacturing processes of MOS transistor, there are required additional processes separated from the manufacturing processes of MOS transistor.

### SUMMARY OF THE INVENTION

It is therefore an object of the present invention to provide a semiconductor device comprising newly-structured antifuse elements which can be formed by using normal manufacturing processes of MOS transistors without any particular processes only for forming the antifuse elements.

According to one aspect of the present invention, a semiconductor device comprises a semiconductor substrate, a MOS transistor and an antifuse element. The MOS transistor is formed on the semiconductor substrate and comprises a channel region and a gate electrode. The channel region has a predetermined conductive type such as a p-type and is formed by a first process. The gate electrode is formed by a second process. The antifuse element is formed on the semiconductor substrate and comprises a predetermined region and an antifuse electrode. The predetermined region has the predetermined conductive type such as p-type and is formed by the first process, i.e. the channel region forming process. The antifuse electrode is formed by the second process, i.e. the gate electrode forming process.

An appreciation of the objectives of the present invention and a more complete understanding of its structure may be had by studying the following description of the preferred embodiments and by referring to the accompanying drawings.

### BRIEF DESCRIPTION OF THE DRAWINGS

FIG. 1 is a cross-sectional view showing a DRAM device in accordance with a first embodiment of the present invention; and

FIG. 2 is a cross-sectional view showing a DRAM device in accordance with a second embodiment of the present invention.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DESCRIPTION OF PREFERRED EMBODIMENTS

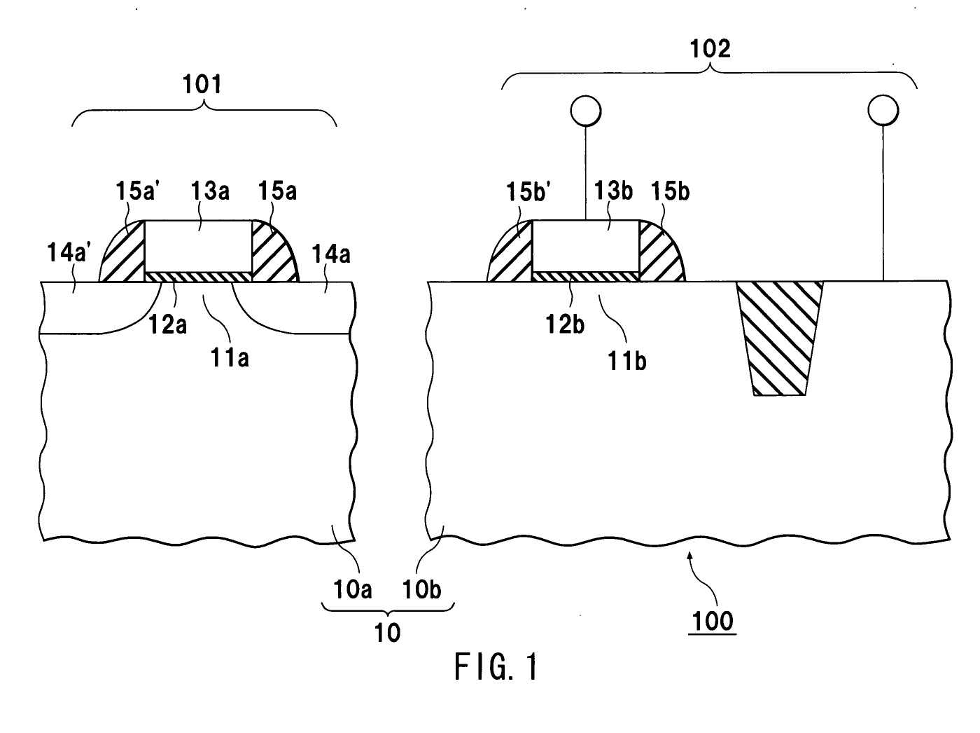

With reference to FIG. 1, a semiconductor device according to a first embodiment of the present invention is a DRAM device 100 which comprises a silicon substrate 10, cell transistors 101 and antifuse elements 102. For the sake of simplification, only one pair of cell transistor 101 and antifuse element 102 is shown in the drawing, and explanation hereinbelow is also directed to only one pair of cell transistor 101 and antifuse element 102.

The cell transistor 101 and the antifuse element 102 are formed on the common substrate 10. In detail, the common substrate 10 includes a p-well region 10a and a p-well region 10b; the cell transistor 101 is formed on the p-well region 10a, while the antifuse element 102 is formed on the p-well region 10b.

The cell transistor 101 is an nMOS transistor, which comprises a channel region 11a, a gate insulator 12a, a gate electrode 13a, source and drain regions 14a, 14a′, and sidewalls 15a, 15a′. The channel region 11a is formed in the p-well region 10a and is of p-type. The gate insulator 12a is formed on the channel region 11a. The gate electrode 13a is formed on the gate insulator 12a and is made of p-type poly-silicon. The source and the drain regions 14a, 14a′ are formed in the silicon substrate 10 and are positioned on the opposite sides of the channel region 11a. The source and the drain regions 14a, 14a′ are of an n-type. The sidewalls 15a, 15a′ are formed on the respective parts of the source and the drain regions 14a, 14a′ and are positioned at the opposite sides of a set of the gate insulator 12a and the gate electrode 13a.

The antifuse element 102 comprises a p-type region 11b, an insulator film 12b, an antifuse electrode 13b and sidewalls 15b, 15b′. The illustrated p-type region 11b constitutes a part of the p-well region 10b and corresponds to the channel region 11a of the cell transistor 101. The illustrated insulator film 12b is formed on the p-type region 11b and corresponds to the gate insulator 12a of the cell transistor 101. The antifuse electrode 13b is formed on the insulator film 12b and corresponds to the gate electrode 13a of the cell transistor 101. In this embodiment, the antifuse electrode 13b is made of p-type poly-silicon. In other words, the antifuse electrode 13b and the region 11b are of a common conductive type in accordance with the present embodiment. The sidewalls 15b, 15b′ are formed on the p-well region 10b and are positioned at the opposite sides of a set of the insulator film 12b and the antifuse electrode 13b. The sidewalls 15b, 15b′ correspond to the sidewalls 15a, 15b′.

The antifuse element 12 of the present embodiment is formed by using the manufacturing processes of the cell transistor 101; any additional processes are not required therefor. In detail, the p-type region 11b is formed simultaneously when the channel region 11a is formed; the insulator film 12b is formed simultaneously when the gate insulator 12b is formed; and the antifuse electrode 13b is formed simultaneously when the gate electrode 13a is formed. The sidewalls 15b, 15b′ are formed simultaneously when the sidewalls 15a, 15a′ are formed, although the sidewalls 15b, 15b′ are not required on a functional aspect of the antifuse element 102.

More in detail, the p-type region 1b is formed by doping p-type impurities such as boron (B) impurities or indium (In) impurities into the silicon substrate 10 in accordance with the normal p-type channel formation process. This embodiment is different from the US 2004/0051162 A1 and does not require the nitrogen implantation process before the formation of the insulator film 12b. In addition, a dose of impurities implanted into the region 11b is equal to that in the channel region 11a of the cell transistor 101 in this embodiment. In detail, the dose to the region 1b belongs to the normal dose for the formation of the channel region 11a, i.e. a range of from 1×10¹¹ to 1×10¹³ ions/cm². Therefore, the concentration of the impurities falls within a rage of from 1×10¹⁶ to 1×10¹⁸ ions/cm³. The p-type region 11b may have other impurity concentration lower than that of the channel region 11a. For example, the p-type region 11b may be masked during the ion-implantation process for the formation of the channel region 11a and may be doped with no impurity.

With the above-explained structure, the antifuse element 102 can be formed by only using the normal formation processes of the cell transistor 101 without any special processes. Therefore, the above structure has an advantage in cost, compared with the technique disclosed in US 2004/0051162 A1. In addition, since the antifuse electrode 13b and the region 11b are of the common conductive type, stable resistance value in the antifuse element 102 can be ensured even after the insulator film 12b is broken so that the impurities of the antifuse electrode 13b are partially moved and diffused into the region 11b.

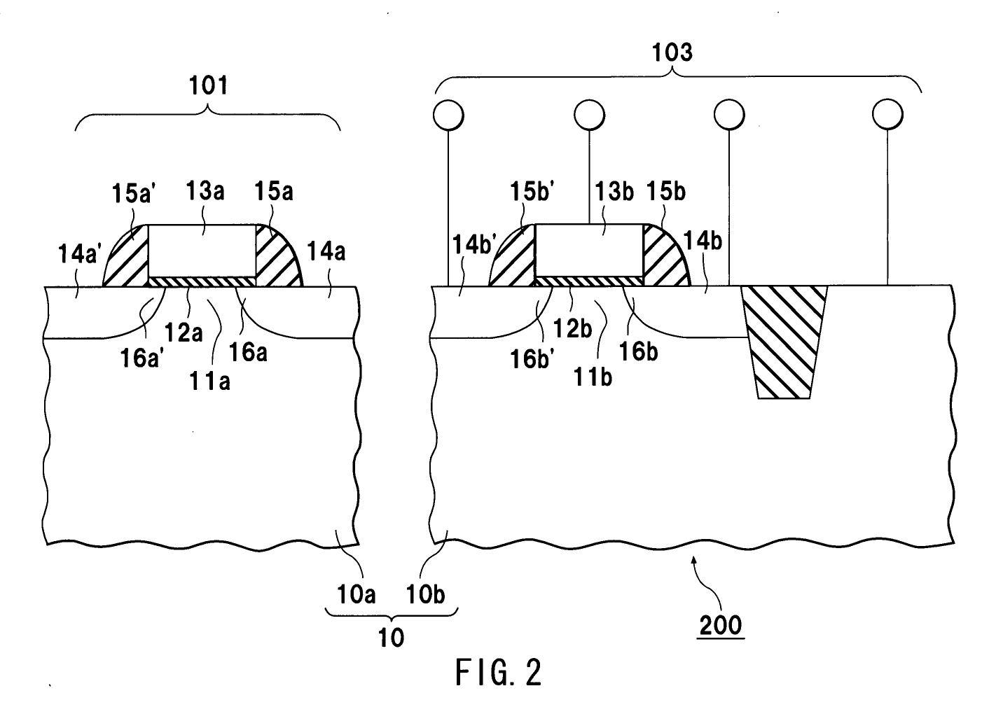

With reference to FIG. 2, a semiconductor device according to a second embodiment of the present invention is also a DRAM device 200 and is a modification of the above-explained first embodiment. The same functional elements or portions are depicted with the same reference numerals or symbols; explanation thereabout is omitted for the sake of clarity.

As shown in FIG. 2, the DRAM device 200 of the present embodiment comprises cell transistors 101 and antifuse elements 103, all of which are formed on the common silicon substrate 10, similar to the first embodiment.

As apparent from FIG. 2, the antifuse element 103 of the present embodiment is of MOS transistor type, which has a very similar structure to a normal MOS transistor. In detail, the illustrated antifuse element 103 comprises not only the structure of the antifuse element 102 of the first embodiment but also first and second regions 14b. The first and the second regions 14b, 14b′ correspond to the source and the drain regions 14a, 14a′ and are of n-type in this embodiment. The first and the second regions 14b, 14b′ are formed upon the source/drain formation process.

More specifically, the first region 14b includes an overlapping region 16b, and the second region 14b′ includes another overlapping region 16b′. The antifuse electrode 13b of the antifuse element 103 is positioned over the overlapping regions 16b, 16b′ with the parts of the insulator film 12b placed therebetween. The overlapping regions 16b, 16b′ may have areas larger than corresponding parts 16a, 16a′ of the source and the drain regions 14a, 14a′, respectively. Because of the overlapping regions 16b, 16b′, the antifuse element 103 can be breakdown at a reduced programming voltage. In addition, since the antifuse electrode 13b is of p-type while the first and the second regions 14b, 14b′ are of n-type in this embodiment, the antifuse element 103 has a lowered resistance if a leakage path is formed between the antifuse electrode 13b and the overlapping region 16b, 16b′.

Although the antifuse element 102 or 103 is formed in the p-well region 10b in each of the above-described embodiments, the present invention is not limited thereto. The antifuse element 102 or 103 may be directly formed on the silicon substrate 10 without forming the p-well region 10b in the silicon substrate 10.

The present application is based on Japanese patent applications of JP2006-012716 filed before the Japan Patent Office on Jan. 20, 2006, the contents of which are incorporated herein by reference.

While there has been described what is believed to be the preferred embodiment of the invention, those skilled in the art will recognize that other and further modifications may be made thereto without departing from the sprit of the invention, and it is intended to claim all such embodiments that fall within the true scope of the invention.

What is claimed is:

1. A semiconductor device comprising a semiconductor substrate, a MOS transistor and an antifuse element, the MOS transistor being formed on the semiconductor substrate and comprising a channel region and a gate electrode, the channel region having a predetermined conductive type and being formed by a first process, the gate electrode being formed by a second process, the antifuse being formed on the semiconductor substrate and comprising a predetermined region and an antifuse electrode, the predetermined region having the predetermined conductive type and being formed by the first process, the antifuse electrode being formed by the second process.

2. The semiconductor device according to claim 1, wherein the gate electrode has the predetermined conductive type.

3. The semiconductor device according to claim 1, wherein the MOS transistor further comprises source and drain regions formed by third and fourth processes, respectively, the antifuse element being of a MOS transistor type and further comprising first and second regions formed by the third and the fourth processes, respectively.

4. The semiconductor device according to claim 3, wherein the MOS transistor further comprises a gate insulator formed by a fifth process, the antifuse element further comprising an insulator layer formed by the fifth process, at least one of the first and the second regions including an overlapping region, the electrode of the antifuse element being positioned over the overlapping region with the a part of the insulator layer placed therebetween.

5. The semiconductor device according to claim 1, wherein the predetermined conductive type is a p-type.

6. The semiconductor device according to claim 1, wherein the predetermined region has a predetermined impurity concentration equal to or less than an impurity concentration of the channel region.

7. The semiconductor device according to claim 6, wherein the predetermined impurity concentration belongs to a range of from 1×10¹⁶ to 1×10¹⁸ ions/cm³.

8. The semiconductor device according to claim 1, wherein the predetermined region is formable by doping impurities of p-type into the semiconductor substrate without any additional nitrogen doping processes.

9. The semiconductor device according to claim 1, wherein the antifuse element is formable by using a manufacturing processes of the MOS transistor without any additional processes.
